(19) United States
(12) Patent Application Publication
(10) Pub. No.: US 2007/0052443 A1
(43) Pub. Date: Mar. 8, 2007

(54) Buffer circuit

(75) Inventors: Atul Katoch, Eindhoven (NL); Sanjeev Kimar Jain, Dehli (IN); Rinze Ida Mechtildis Peter Meijer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/556,005

(22) PCT Filed: May 7, 2004
(86) PCT No.: PCT/IB04/50613

§ 371 Date: Nov. 8, 2005

(30) Foreign Application Priority Data
May 12, 2003 (EP) 03101317.0

(51) Int. Cl. H03K 19/003

(52) U.S. Cl. 326/31

(57) ABSTRACT

A buffer circuit (31), for example a repeater or receiver circuit for a signal wire of an on-chip bus, receives an input signal, and produces an output signal. The buffer circuit (31) comprises a first inverting stage (7) and a second inverter stage (9). The second inverting stage (9) provides the drive for the output (5). The first inverting stage (7) has additional circuitry (15, 17, 19, 21, 23, 25, 27, 29) for controlling the strengths of the pull up path and the pull down path. The pull up/down paths are dynamically controlled according to the status of one or more aggressor signals. In one embodiment the switching threshold is lowered only in the worst case delay scenario, i.e. when the signal wire (3) is at a different logic level to the aggressor signals. In another embodiment, the switching threshold is raised when the signal wire and aggressor signals are all at the same logic level, thereby reducing crosstalk.

The invention relates to a buffer circuit, and in particular, to a buffer circuit acting as a repeater or receiver on a signal wire of an integrated circuit, such as a signal wire of an on-chip bus.

As integrated circuit technology is scaled to provide increased density on a chip, the on-chip interconnects become narrower and narrower. In addition, the height of the on-chip interconnects tend not to be scaled linearly with the width of the interconnects, thus making their aspect ratios larger. These trends lead to an increase in coupling capacitance with neighboring wires, which in turn leads to increased crosstalk between wires. These degrading effects, coupled with high wire resistance, can lead to poor performance due to the poor RC response at the receiving end of the wire.

This scenario is further degraded on an on-chip bus system when neighboring wires (referred to hereinafter as “aggressor” wires) switch in opposite directions to a wire under consideration (referred to hereinafter as a “victim” wire). For example, on a typical bus, the delay due to worst case switching, which occurs when the aggressor wires switch in an opposite direction to the victim wire, can be up to 2-4 times higher than when the wires switch in the same direction. Glitches due to crosstalk may occur on a victim wire when it stays silent and the aggressor wires switch simultaneously in the same direction.

It is known to overcome the problems mentioned above by reducing the coupling length of on-chip interconnects. One method for reducing coupling length is to introduce repeaters in each bus wire. A traditional repeater is a buffer circuit comprising two inverting stages. A repeater helps to reduce the crosstalk between bus wires, and also assists in linearizing the dependency of delay over the wire length.

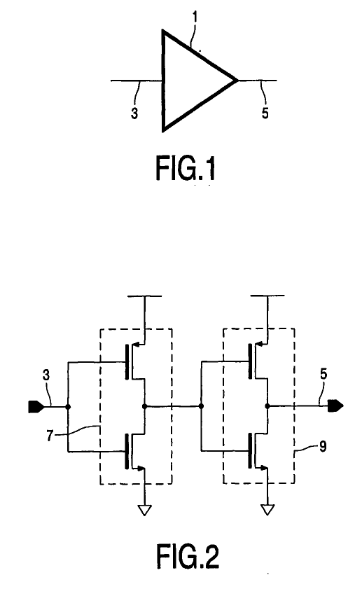

FIG. 1 shows a schematic diagram of a typical repeater circuit 1 connected in the path of a signal wire, such that the repeater circuit 1 receives an input signal 3 and produces an output signal 5. A typical circuit for realizing the repeater of FIG. 1 is shown in FIG. 2. The repeater circuit 1 comprises first and second inverting stages 7, 9 connected in series, which are properly sized for driving a particular load. The switching threshold of the repeater circuit 1 is Vdd/2, where Vdd is the supply voltage. Although the repeater circuit of FIG. 2 is useful for reducing the coupling length, which in turn reduces crosstalk between wires on a bus, such a repeater circuit still suffers from poor performance due to poor RC response at the receiving end of a wire segment.

Techniques usually used for reducing delays and delay noise are repeater insertion and delayed switching schemes. However, such schemes still suffer from poor response on long wires due to high wire capacitance (and miller coupling), since the switching threshold of the repeaters and receivers is fixed at half the supply voltage, i.e. Vdd/2.

Although it is known to lower the switching thresholds of repeaters by utilizing Schmitt trigger types of circuits, the improvement in bus performance is offset by the increased susceptibility to glitches caused by crosstalk. Furthermore, the charge induced by crosstalk can grow as it travels along a wire, leading to increased delay noise and hence slow speed.

An object of the present invention is to provide a buffer circuit for a signal wire on an integrated circuit, for example a buffer circuit acting as a repeater or receiver on a signal wire of an on-chip bus, which suffers less from the disadvantages mentioned above.

According to a first aspect of the present invention, there is provided a buffer circuit for a signal wire of an integrated circuit in which one or more aggressor signals can have a degrading effect on the signal wire, the buffer circuit receiving an input signal and producing an output signal, and comprising first and second inverter stages, characterized in that the buffer circuit comprises means for dynamically controlling the switching threshold of the first inverting stage according to the state of one or more of the aggressor signals.

According to another aspect of the present invention, there is provided a method of buffering a signal on a signal wire of an integrated circuit in which one or more aggressor signals can have a degrading effect on the signal, the method comprising the step of receiving an input signal and producing an output signal using first and second inverter stages, the method being characterized by the step of dynamically controlling the switching threshold of the first inverting stage according to the state of one or more of the aggressor signals.

According to another aspect of the present invention, there is provided an integrated circuit with an on-chip bus, having a buffer circuit as defined in the claims.

Advantageous embodiments are defined by the dependant claims.

For a better understanding of the present invention, and to show more clearly how it may be carried into effect, reference will now be made, by way of example, to the accompanying drawings, in which:

FIG. 1 shows a schematic diagram of a repeater circuit according to the prior art;

FIG. 2 shows further details of the repeater circuit of FIG. 1;

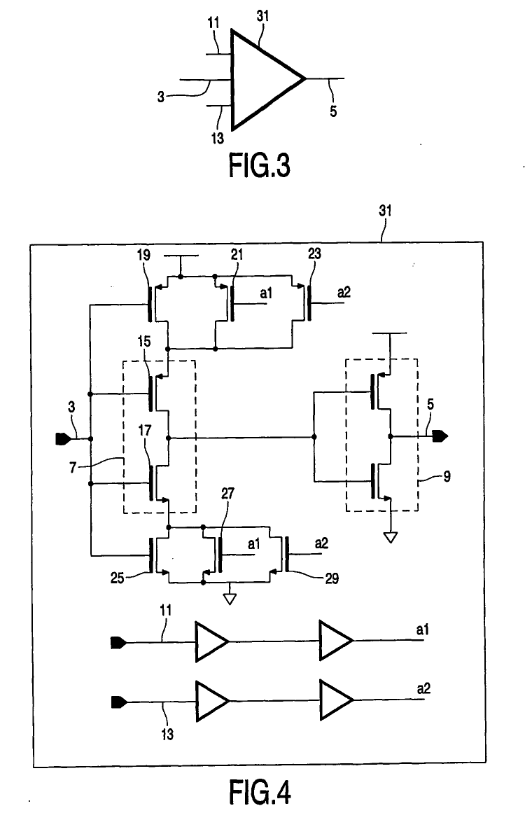

FIG. 3 shows a schematic diagram of a repeater circuit according to the present invention;

FIG. 4 shows in greater detail a repeater circuit according to a first aspect of the present invention;

FIG. 5 shows a repeater circuit according to another aspect of the present invention;

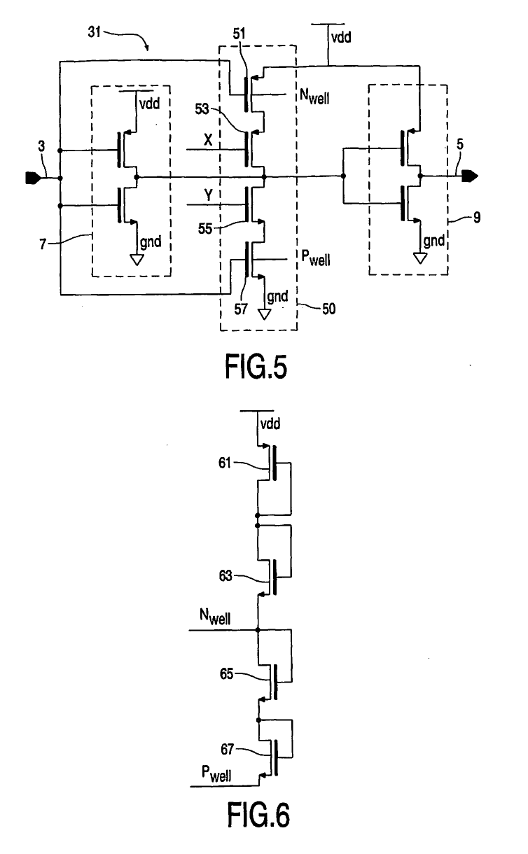

FIG. 6 shows further details of a bias circuit for the repeater circuit of FIG. 5;

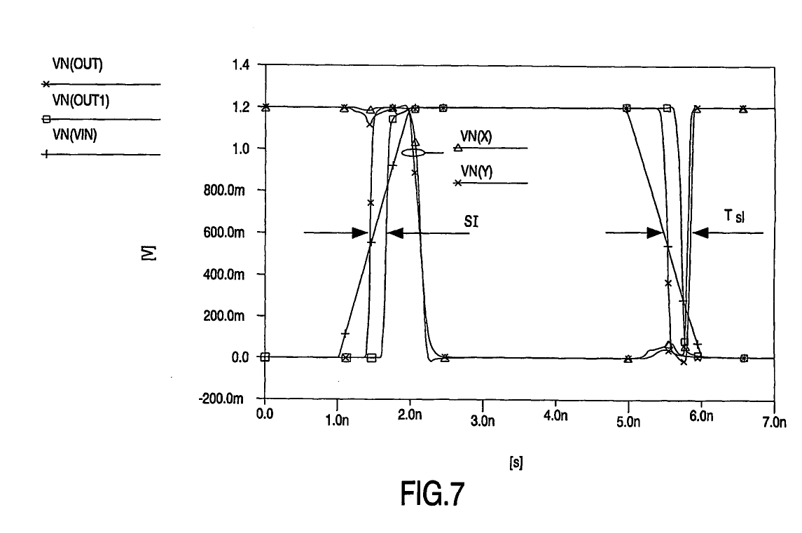

FIG. 7 shows simulation waveforms for the repeater circuit of FIG. 5;

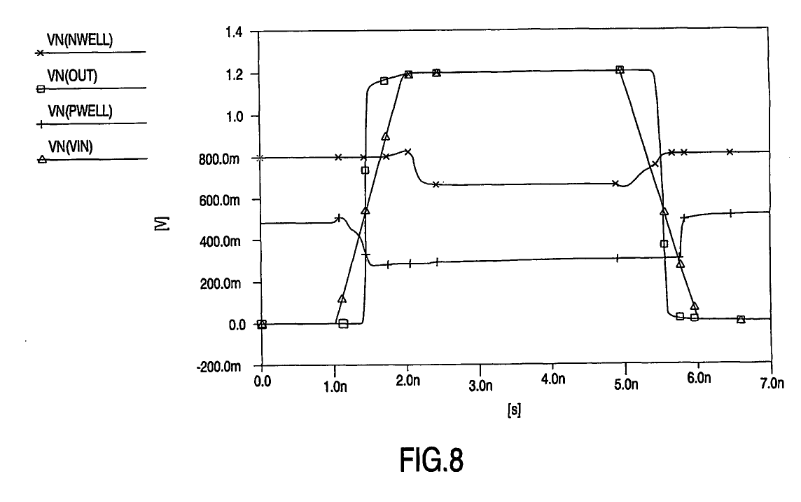

FIG. 8 shows N-well and P-well bias for the circuit shown in FIG. 6;

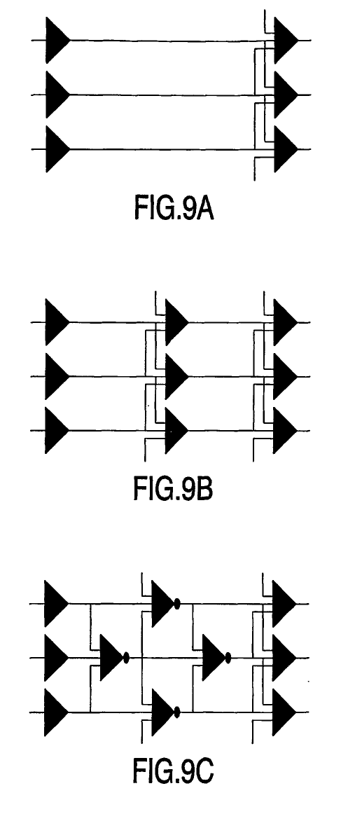

FIGS. 9a to 9c show how the repeater circuit of the present invention can be connected as a repeater in an on-chip bus system;

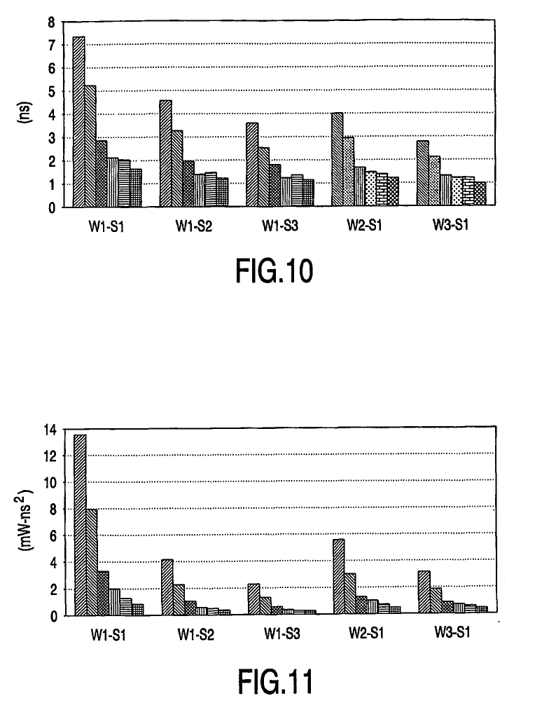

FIG. 10 shows a comparison of worst-case delays between the present invention and the prior art;

FIG. 11 shows a comparison of power-delay² between the present invention and the prior art; and

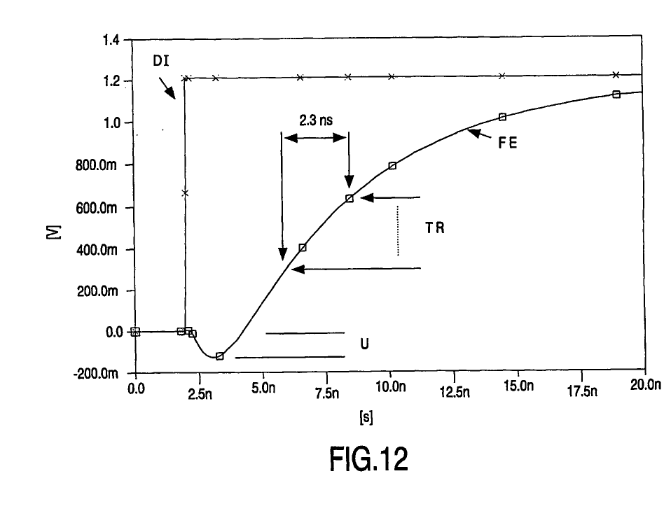

FIG. 12 shows how varying or adapting the switching threshold of a repeater circuit can affect the circuit delay.

FIG. 3 shows a schematic diagram of a repeater circuit, or more generally a buffer circuit, according to the present invention. As mentioned above, a buffer circuit can be used as a repeater or a receiver on a signal wire of an integrated circuit. Thus, although the following description of the preferred embodiments relate to the use of the buffer circuit as a repeater, it will be appreciated that the buffer circuit can also be used a receiver.

As with a conventional repeater, the repeater circuit 31 of FIG. 3 is located in the path of a signal wire (i.e. victim wire), such that it receives an input signal 3 and produces an output signal 5. However, according to the present invention, the repeater circuit 31 also receives aggressor signals 11, 13. The aggressor signals are taken, for example, from neighboring wires to the victim wire on an on-chip bus system. The aggressor signals 11, 13 are used to control the operation of the repeater circuit, such that the switching threshold of the repeater circuit 31 is dynamically changed during operation, depending on the status of the aggressor signals 11, 13.

According to one aspect of the invention, the switching threshold of the repeater circuit 31 is lowered when the aggressor signals 11, 13 are in certain states only, for example when the switching of the aggressor signals can potentially cause worst-case delay. This occurs when the aggressor wires switch in an opposite direction to the victim wire. It is noted that “lowering the switching threshold” can involve either lowering or raising the switching voltage of the repeater, depending upon whether the transition of the signal on the victim wire is from logic 0 to 1, or from logic 1 to 0.

In other words, during a transition from logic 0 to logic 1, the normal switching threshold is lowered by lowering the normal switching voltage (for example Vdd/2) by a value “Δ” to (Vdd/2)−Δ. This results in the repeater being made more sensitive to the input transition from 0 to 1. Likewise, when switching from logic 1 to logic 0, the switching threshold is lowered by raising the switching voltage by a value “Δ” to (Vdd/2)+Δ, which makes the repeater more sensitive to an input transition from 1 to 0.

Table 1 below shows how the switching threshold of the repeater circuit 31 is dynamically changed according to the various states of the victim and aggressor wires.

As can be seen from the table, the switching threshold of the repeater circuit

TABLE 1
Aggressor aware repeater thresholds at various states

| | | | | Gain over |
|---|---|---|---|---|
| Victim | Aggressor state | Repeater | Aggressor-aware | traditional |
| state | (agg1, agg2) | Threshold | Repeater Threshold | repeater |
| 0 | 1, 1 | Vdd/2 | Vdd/2 − Δ | Faster speed |
| 0 | 1, 0 | Vdd/2 | Vdd/2 | No gain |
| 0 | 0, 0 | Vdd/2 | Vdd/2 + Δ | Higher noise |
| | | | | margin |
| 1 | 0, 0 | Vdd/2 | Vdd/2 + Δ | Faster speed |
| 1 | 1, 0 | Vdd/2 | Vdd/2 | No gain |
| 1 | 1, 1 | Vdd/2 | Vdd/2 − Δ | Higher noise |
| | | | | margin |

31 is lowered only when the switching of aggressor signals 11, 13 can potentially cause worst-case delay (i.e. when they switch in an opposite direction to the victim wire). This is shown in the first and fourth rows of the table. In the first row, the victim wire is at logic 0 and the aggressor wires are at logic 1, and the switching threshold is lowered by changing the switching voltage of the repeater to be (Vdd/2)−Δ. In the fourth row, where the victim wire is at logic 1 and the aggressor wires are at logic 0, the switching threshold is lowered by raising switching voltage of the repeater to (Vdd/2)+Δ.

This aspect of the invention has the advantage that, lowering of the switching threshold in these specific situations does not degrade signal integrity, because in such states the noise is always induced in such a way that it cannot introduce a glitch on the victim wire, as will be explained in greater detail later in the application.

FIG. 4 shows a first embodiment for realizing the repeater circuit 31 of FIG. 3. As with the conventional repeater described in FIG. 2, the repeater circuit 31 receives an input signal 3, and produces an output signal 5. The repeater circuit comprises a first inverting stage 7 and a second inverter stage 9. The second inverting stage 9 (which provides the drive for the output 5) comprises a standard inverter circuit as found in FIG. 2. However, the first inverting stage 7 has additional circuitry for controlling the strengths of the pull up path (15, 19, 21, 23) and the pull down path (17, 25, 27, 29), thereby controlling the switching threshold of the repeater circuit according to the status of the aggressor signals 11, 13. The additional circuitry is controlled by delayed values a1, a2 of the aggressor signals 11, 13, respectively.

Using the delayed aggressor values a1, a2, the switching threshold (Vdd/2, Vdd/2±Δ) of the repeater circuit 31 is determined by the state of aggressor signals 11, 13 as previously shown in Table 1 above. For example, assume that the input signal 3, i.e. the victim, is at logic level 0 and the aggressor signals 11, 13 are at logic level 1. This forms the initial condition for a possible worst case switching. This means that a1 and a2 will be at logic 1, resulting in devices 27 and 29 being turned ON while devices 21 and 23 are turned OFF. Thus, the inverting stage 7 has a stronger puff down path as compared to the pull up path, which means that this stage becomes more sensitive to 0→1 transitions at its inputs.

As mentioned above, the lowering of the switching threshold only when worst-case switching for delay is expected does not degrade signal integrity because the noise is always induced such that it cannot lead to a glitch at the output of a repeater/receiver. This phenomenon is explained as follows:

If it is assumed that the victim wire is at logic level 0 and the aggressor wires (neighbors) are at logic level 1, then “worst-case” switching for delay can occur in this state, which leads to a larger delay as compared to all the other cases. In this state, when the victim wire remains unchanged at logic level 0 and the aggressor wires switch from logic level 1 to logic level 0, the noise induced takes the victim wire to a voltage which is lower than logic level 0.

Similarly, worst-case switching for delay can also occur if the victim wire is at logic level 1 and the aggressor wires (neighbors) are at logic level 0. When the victim wire remains unchanged at logic level 1 and the aggressor wires switch from logic level 0 to logic level 1, the noise induced takes the victim wire to a voltage which is higher than logic level 1.

Only in the above-mentioned states can worst-case switching for delay occur. In all other cases (i.e. other states of the bus wires) the delay is less than the worst-case delay. This means that the noise induced in this state cannot cause a glitch at the receiver and so the switching threshold of the repeater/receiver can be safely reduced.

According to another aspect of the invention, the embodiment shown in FIG. 4 can also be used to raise the switching threshold to avoid glitches at the outputs of the repeater/receiver. Crosstalk noise, which can be potentially harmful to signal integrity, is induced when the victim and aggressors are in the same state, and the aggressor wires switch while the victim stays quiet. Preferably, in this state, the threshold of the repeater circuit is raised, which reduces the chances of glitches being propagated and hence improves signal integrity. However, this happens at the cost of higher typical-case delay, which does not degrade bus performance.

For example, if all the three wires are at the same logic level (e.g. 0) then a1 and a2 are also at 0. This forms the initial case for a possible worst case switching for crosstalk noise, which may lead to a glitch if the victim does not switch and both the aggressors switch. In this case, the switching threshold is raised. Since a1 and a2 are at 0, this results in devices 21 and 23 being turned ON and devices 27 and 29 being turned OFF. This means that the pull up strength of the inverter 7 is higher than the pull down strength. This makes the repeater less sensitive to a 0→1 transition and hence more robust As mentioned above, the control signals a1 and a2 are delayed signals derived from the neighboring wires. The delay is essential as these delay lines act as a temporary state retention elements, which prepare the circuit for the next transition.

In a similar manner to lowering the switching threshold, the raising of the switching threshold also involves the lowering or raising of the switching voltage, depending upon whether a transition from 1 to 0 or from 0 to 1 is expected.

FIG. 5 shows a second embodiment for realizing the repeater circuit 31 of FIG. 3. As with a conventional repeater as shown in FIG. 2, the repeater circuit 31 comprises a first inverting stage 7 and a second inverting stage 9. The second inverting stage 9 of the repeater circuit 31 comprises a standard inverting circuit, and provides the drive for the output signal 5. However, unlike the conventional repeater of FIG. 2, the first inverting stage 7 has additional circuitry 50 connected in parallel thereto. The additional circuitry 50 has selectable pull up/down paths, thereby enabling the pull up/down paths of the first inverting stage to be controlled in accordance with control signals X, Y. The control signals X, Y are derived from the aggressor signals.

The lowest possible switching threshold depends upon the threshold voltage of N (pull-down) and P (pull-up) devices when one of the paths is selected (either pull up or pull down).

The additional circuitry 50 comprises a first p-mos device 51 having its source connected to Vdd and its drain connected to a second p-mos device 53. The gate of p-mos device 51 is controlled by the input signal 3 (i.e. Vin). The gate of the second p-mos device 53 is controlled by the control signal X. The drain of the second p-mos device 53 is connected to the output of the first inverter stage 7, the input of the second inverter stage 9, and the drain of a first n-mos device 55. The source of the first n-mos device 55 is connected to the-drain of a second n-mos device 57, and the gate of the first n-mos device 55 is controlled by the second control signal Y. The gate of the second n-mos device 57 receives the input signal 3 (i.e. Vin), and the source of the second n-mos device 57 is connected to ground.

The control signals X, Y are derived using selection logic (not shown), based on the status of the input signal 3 of the repeater (i.e. Vin) and the aggressor signals 11 and 13 (referred to below as Agg1 and Agg2, respectively). The selection logic is configured such that:
X= V̅i̅n̅·Agg1·Agg2
Y= V̅i̅n̅+Agg1+Agg2

The selection logic is implemented in such a way that the delay meets the following criterion:
T_{CLK}>T_{Sl}>δₘₐₓ (1)

Where, T_{CLK} is the clock period, T_{Sl} is the delay of selection circuit, δₘₐₓ is the maximum difference between the delay of the wire section that is being refreshed by the repeater and its aggressors. The lower bound on T_{Sl} ensures that the state selection is maintained until the input of the repeater has crossed Vdd/2 and the first inverting stage 7 has switched. Otherwise the internal node of the repeater circuit could flip temporarily, which would cause a short glitch.

In the embodiment described above, the aggressor signals 11 (Agg1) and 13 (Agg2) represent the signals on the immediate aggressors to the victim wire under consideration. The first inverter stage 7, or “weak” inverter, in FIG. 5 acts to keep the state on the internal node of the repeater circuit 31 when the path selection and the input state are such that the internal node is tri-stated.

The additional circuitry 50 operates to lower the switching threshold of the repeater circuit 31 only when worst-case switching is expected, and does not raise the threshold when typical-case switching is expected. This is achieved by having a “weak” first inverting stage 7, with the additional circuitry 50 connected in parallel such that the pull up/down paths of the inverter stage 7 and additional circuitry 50 combine to form the total pull up/down paths.

When the victim wire is in an opposite state as compared to the aggressor wires, then either of devices 53 or 55 is selected, which results in the input stage being more sensitive to low or high transitions respectively. However, if all wires are in the same state, then both devices 53 and 55 are turned ON, and thus the switching threshold remains at Vdd/2.

This arrangement enables the repeater circuit 31 to be configured such that the switching threshold of the repeater circuit is lowered only when worst-case switching for delay is expected (i.e. when the victim wire is in an opposite state to the aggressor wires), and in all the other states the switching threshold is kept constant, for example at Vdd/2. In contrast, the repeater circuit described in FIG. 4 increases the typical-case delay as it also targets high robustness, by increasing the threshold of the repeater circuit during certain states, i.e. when all wires are in the same state, and the victim wire stays constant and the aggressor wires switch, or vice-versa.

According to the circuit arrangement of FIG. 5, it is possible to reduce the delay of the bus in the case when the victim and one of its aggressors switch in opposite directions, corresponding to the highlighted rows in Table 1.

The lowest possible switching threshold of the repeater circuit of FIG. 5 can be further lowered using triple well technology by providing a local well bias voltage. A local bias circuit is implemented by connecting p-mos (61) and n-mos (63, 65, 67) transistors with their gate drain shorted together, as shown in FIG. 6. The sizes of these transistors can be the minimum dimensions allowed by the technology as they have to bias very small wells. This circuitry is provided to locally bias the p-well and n-well of devices 51 and 57, while the remaining circuitry is globally biased. This further enhances the performance of the circuit, since it is then possible to further reduce the threshold voltages and thus the switching thresholds. This feature is particularly suited for SOI (Silicon On Insulator) technology.

FIG. 7 shows simulation waveforms (Voltage [V] versus Time [s]) for the repeater circuit of FIG. 5. The applied input has a rise/fall time of Ins, which corresponds to a typical repeater spacing of about 2 to 3 mm. The VN(OUT) signal is the output 5 of the repeater circuit of FIG. 5, while the VN(OUT1) signal is the output of a conventional repeater during the state when worst-case switching for delay occurs. SI indicates the speed improvement resulting from the invention.

FIG. 8 shows the N-well and P-well bias for the aggressor aware repeater circuit according to FIG. 4. The offsets show the bias voltages for P and N well for the devices 57 and 51 respectively. A higher than “gnd” value of p-well indicates that the threshold is lowered, and likewise for the n-well bias.

FIGS. 9a to 9c show how the repeater circuit according to the present invention can be inserted into signal wires of an on-chip bus. FIG. 9a shows a point-to-point connection. FIG. 9b shows a repeater insertion. FIG. 9c shows a staggered repeater insertion. The choice of repeater insertion technique depends upon practical aspects. For example, repeater insertion can be used to reduce the quadratic dependence on delay to a linear one. Staggered insertion can provide good results, but at the cost of being more difficult to place the repeaters during the layout of the integrated circuit Likewise, parallel repeater insertion can also be difficult to implement, although usually easier than staggered repeater insertion. Thus, it can be seen that the insertion technique depends to a large extent on the various designs constraints and layout aspects of a particular integrated circuit.

The repeater circuit according to the present invention provides improved performance as described below. The performance simulations are based on a 10 mm long bus on a second metal layer laid over metal one plane in CMOS 0.13 micrometer technology. A simulation-based approach is used to calculate the repeater sizes, i.e. the drive strength for a given load, based on optimum power-delay product

A distributed wire RLC (resistance-inductance-capacitance) model is used to model the wires. A comparison of speed and power dissipation is provided for a conventional repeater and the repeater according to the present invention, both having the same output drives for different configurations, no repeater insertion, repeater insertion and staggered repeater insertion as shown in FIG. 9. For staggered repeater insertion an inverting stage is inserted before the output inverter (FIG. 5) for having inverted outputs.

Tables 2 and 3 show the worst-case delay and product of the power and the square of the delay (i.e. Power-Delay² product) for a 10 mm long bus laid at minimum pitch. 125 MHz data rate is used for simulating the power Figs.

TABLE 2
Worst-case delay (ns) for 10 mm bus laid
at minimum pitch for various schemes.

| | | Aggressor | Percentage |
|---|---|---|---|
| Scheme | Traditional | aware | improvement |
| No | 7.39 | 5.26 | 28.8 |
| repeaters | | | |
| Parallel | 2.90 | 2.12 | 26.9 |
| repeaters | | | |
| Staggered | 2.08 | 1.72 | 17.3 |
| repeaters | | | |

TABLE 3
Power-Delay² (mW-ns²) product for 10 mm bus various schemes.

| | | Aggressor | Percentage |
|---|---|---|---|
| Scheme | Traditional | aware | improvement |
| No | 13.43 | 7.91 | 41.10 |
| repeaters | | | |
| Parallel | 3.38 | 2.00 | 40.84 |
| Repeaters | | | |
| Staggered | 1.31 | 0.92 | 29.77 |
| repeaters | | | |

FIGS. 10 and 11 show worst-case delay and Power-delay² product for a bus laid out at various pitches. W1-S1 refers to minimum width and minimum spacing and W1-S2 refers to minimum width and two times the minimum spacing and so on. It can be seen from the Figs. that gains are maximum at minimum pitch, thereby confirming that the repeater of the present invention is suited for future technologies where coupling capacitance and wire resistance will both increase. For each situation, the columns show from left to right no repeater; an aggressor-aware receiver, repeater insertion; aggressor-aware repeaters; staggered repeaters; and aggressor aware staggered repeaters.

Although the preferred embodiment has been described in relation to the switching threshold being dynamically lowered according to first and second aggressor signals, for example from immediate neighbors, it will be appreciated that the aggressor signals may be derived from any signal wires on the integrated circuit which can have an impact on the victim wire. For example, the repeater circuit can be used to reduce the effect of crosstalk from far-away aggressors, when the victim wire and its immediate aggressor wires are not switching, but whereby other aggressor wires are switching to generate noise. In such a state, the simulation results show that a peak noise of 225 mV was observed on the victim line due to simultaneous switching of six far off aggressors (three on each side) (total nine wires, 6 far-away aggressors, 2 immediate aggressors and 1 victim).

FIG. 12 shows a signal waveform at the far end of a 10 mm long interconnect, illustrating how varying or adapting the switching threshold of a repeater can have a significant impact on the delay. DI denotes Driver Input, FE denotes Far End, TR denotes Threshold Range; and U denotes Undershoot.

The invention described above provides a buffer circuit for use as a repeater or receiving circuit, in which the switching threshold is dynamically changed in accordance with the state of one or more aggressor wires. The buffer circuit has the advantage of improving the performance of the bus.

In the examples provided above, it is assumed that the close neighbors of the victim wire induce most of the noise and the noise induced by subsequent aggressor is lesser. However, it will be readily apparent to a person skilled in the art that, although the preferred embodiments refer to the aggressor wires being the immediate neighbors of the victim wire, the aggressor wires could also be selected from other signal wires which have an impact on the victim wire. For example the aggressor wires can be signal wires other than the immediate neighbors of the victim wire, or from a different communication bus which is synchronous with the bus under consideration. Furthermore, the reference to immediate neighbors embraces both immediate neighbors in the same plane and neighbors lying in different planes, for example above and below the metal plane under consideration.

In addition, it is noted that the invention can be used with only one aggressor signal, for example when the buffer is used as a repeater/receiver near the edge of a communication bus, or with more than two aggressor signals, for example when second order or third order crosstalk is being experienced.

Also, other modifications are possible without departing from the scope of the invention as defined in the appended claims. For example, a person skilled in the art will appreciate that various circuit elements shown in the preferred embodiments can be replaced with equivalent circuits performing the same function. For example, in FIG. 5 the devices 55 and 56 can be interchanged, as can the devices 51 and 53.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of a hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A buffer circuit (31) for a signal wire of an integrated circuit in which one or more aggressor signals can have a degrading effect on the signal wire, the buffer circuit (31) receiving an input signal and producing an output signal, and comprising first and second inverter stages (7, 9), characterized in that the buffer circuit (31) comprises means (19, 21, 23, 25, 27, 29) for dynamically controlling the switching threshold of the first inverting stage (7) according to the state of one or more of the aggressor signals.

2. A buffer circuit (31) as claimed in claim 1, wherein the means (19, 21, 23, 25, 27, 29) for dynamically controlling the switching threshold receives first and second aggressor signals for controlling the switching threshold.

3. A buffer circuit (31) as claimed in claim 2, wherein the means (19, 21, 23, 25, 27, 29) for dynamically controlling the switching threshold comprises means for lowering the switching threshold when the signal wire is at a first logic level, and the first and second aggressor signals are at a second logic level.

4. A buffer circuit (31) as claimed in claim 3, wherein the switching threshold is lowered by lowering the switching voltage of the first inverting stage (7) when the signal wire is at a low logic level.

5. A buffer circuit (31) as claimed in claim 3, wherein the switching threshold is lowered by raising the switching voltage of the first inverting stage (7) when the signal wire is at a high logic level.

6. A buffer circuit (31) as claimed in claim 2, wherein the means (19, 21, 23, 25, 27, 29) for dynamically controlling the switching threshold comprises means for raising the switching threshold when the signal wire and the first and second aggressor signals are at the same logic level.

7. A buffer circuit (31) as claimed in claim 2, wherein the switching threshold is dynamically controlled for a predetermined period of time, using first and second aggressor signals which are delayed versions of the aggressor signals received from corresponding aggressor signal wires.

8. A buffer circuit (31) as claimed in claim 1, wherein the means (19, 21, 23, 25, 27, 29) for dynamically controlling the switching threshold comprises means for selectively controlling a pull up path and/or a pull down path in the first inverter stage (7).

9. A buffer circuit (31) as claimed in claim 3, wherein the means for lowering the switching threshold comprises:
additional circuitry connected in parallel to the first inverter stage (7), the additional circuitry receiving first and second control signals (X, Y) for selectively controlling the respective pull up path and pull down path of the first inverter stage (7).

10. A buffer circuit (31) as claimed in claim 9, wherein the additional circuitry comprises:
first and second p-mos devices connected in parallel to the pull up path of the first inverting stage (7), the first p-mos device having a source connected to a supply voltage (Vdd) and a drain connected to a second p-mos device, the gate of p-mos device being controlled by the input signal, and the gate of the second p-mos device being controlled by the first control signal (X), the drain of the second p-mos device connected to the output of the first inverter stage (7);
first and second n-mos devices connected in parallel to the pull down path of the first inverting stage (7), the first n-mos device having a drain connected to the output of the first inverting stage (7) and a source connected to the drain of the second n-mos device, the gate of the first n-mos device being controlled by the second control signal (Y), and the gate of the second n-mos device receiving the input signal, and the source of the second n-mos device being connected to ground (gnd).

11. A buffer circuit (31) as claimed in claim 10, further comprising selection logic for providing the control signals (X, Y) according to the following equations:
X= V̅i̅n̅·Agg1·Agg2
Y= V̅i̅n̅+Agg1+Agg2
where Vin is the input signal, and Agg1 and Agg2 are the first and second aggressor signals, respectively.

12. A buffer circuit (31) as claimed in claim 11, whereby the selection logic is implemented to meet the following delay criteria:
T_{CLK}>T_{Sl}>δₘₐₓ
where, T_{CLK} is the clock period, T_{Sl} is the delay of selection logic circuit, δₘₐₓ is the maximum difference between the delay of the signal input and the aggressor signals.

13. An integrated circuit having an on-chip bus, wherein one or more signal wires in the on-chip bus include a repeater or receiver circuit having a buffer circuit (31) as defined in claim 1.

14. An integrated circuit as claimed in claim 13, having repeater circuits (31) connected in a point-to-point arrangement.

15. A method of buffering a signal on a signal wire of an integrated circuit in which one or more aggressor signals can have a degrading effect on the signal, the method comprising the step of receiving an input signal and producing an output signal using first and second inverter stages (7,9), the method being characterized by the step of dynamically controlling the switching threshold of the first inverting stage (7) according to the state of one or more of the aggressor signals.
